(19) United States
(12) Patent Application Publication
(10) Pub. No.: US 2025/0216429 A1
(43) Pub. Date: Jul. 3, 2025

(54) APPARATUS AND METHOD FOR DETECTING RELATIVE PHASE

(71) Applicant: ELECTRONICS AND TELECOMMUNICATIONS RESEARCH INSTITUTE, Daejeon (KR)

(72) Inventors: Seunghyun Jang, Daejeon (KR); Sunwoo Kong, Daejeon (KR); Bong Hyuk Park, Daejeon (KR); SEUNG HUN WANG, Daejeon (KR); HUI DONG LEE, Daejeon (KR); Jung Hwan Hwang, Daejeon (KR)

(21) Appl. No.: 19/001,886

(22) Filed: Dec. 26, 2024

(30) Foreign Application Priority Data
Dec. 27, 2023 (KR) 10-2023-0193077

(51) Int. Cl. G01R 25/00

(52) U.S. Cl. CPC G01R 25/00

(57) ABSTRACT

The present disclosure relates to an apparatus and a method for detecting a relative phase. The apparatus includes: a signal superposition unit configured to receive and switch a first input signal and a second input signal having a phase delay θ_{d} with respect to the first input signal so that the first input signal and the second input signal pass through a sensing resistor or a sensing capacitor, respectively, and to superpose and output the passed signals; a signal power detection unit configured to detect power of the signal output from the signal superposition unit; and a differential signal detection unit configured to generate a differential signal for the power of the signal output according to the switching of the first input signal and the second input signal in the signal superposition unit, and to detect the differential signal that changes according to the phase delay θ_{d}.

### CROSS-REFERENCE TO RELATED APPLICATION

This application claims the benefit of Korean Patent Application No. 10-2023-0193077 filed on Dec. 27, 2023, which is hereby incorporated by reference as if fully set forth herein.

### BACKGROUND

### 1. Technical Field

The present disclosure relates to an apparatus and a method for detecting a relative phase, and an apparatus and a method for detecting a relative phase, which can minimize a circuit and measure a relative phase of a signal with a simple structure by switching a first input signal and a second input signal having a phase delay θ_{d} with respect to the first input signal so that the first input signal and the second input signal pass through a sensing resistor or a sensing capacitor, respectively, generating a differential signal for the power of the signal output according to the switching of the first input signal and the second input signal, and detecting the differential signal that changes according to the phase delay θ_{d}.

### 2. Related Art

A phase detection device that detects a phase difference between two high-frequency band signals with different phases may be applied to various fields requiring phase information detection. For example, the phase detection device may be used to detect the phase of a reflected wave occurring between a transmitter and a load in a communication system.

In a case where an output signal of the transmitter in the communication system is transmitted to the load, when impedance mismatch exists, the following various problems may occur. For example, there may occur problems such as signal quality degradation and low signal transmission efficiency due to signal loss, standing wave generation due to reflected waves, harmonic generation due to impedance mismatch, and self-interference due to reflected waves.

In order to solve such problems, impedance mismatch compensation is required, and several methods for the impedance mismatch compensation may exist.

One method is to measure the magnitude and phase of a reflected wave and then design an impedance matching network that corrects the mismatch through a tool such as a Smith chart. To achieve this, the first and foremost task is to measure the magnitude and phase of the reflected wave.

FIG. 1 is a diagram illustrating an apparatus for detecting a relative phase in the related art.

FIG. 1 illustrates, as the apparatus for detecting a relative phase in the related art, an example of an ADL5960 chip manufactured by Analog Device Co., Ltd for detecting information on the magnitude and phase of reflected waves.

Referring to FIG. 1, in signal processing for extracting phase information of a reflected wave, since a radio frequency (RF) frequency band is usually too high for signal processing, the RF frequency band is converted to an inter-mediate frequency (IF) band that is a lower frequency band easy for signal processing, and then information on the magnitude and phase information of a reflected wave signal is extracted through digital signal processing.

Since such a frequency conversion process requires a mixer and a local oscillator 10, the complexity of hardware for detecting the phase of the reflected wave increases and a significant amount of power is required.

Therefore, as an apparatus for detecting the relative phase of a reflected wave for impedance mismatch correction, an apparatus with a simple structure and low power consumption and a method thereof are required.

### SUMMARY

Various embodiments are directed to providing an apparatus and a method for detecting a relative phase, which can minimize a circuit and measure a relative phase of a signal with a simple structure by switching a first input signal and a second input signal having a phase delay θ_{d} with respect to the first input signal so that the first input signal and the second input signal pass through a sensing resistor or a sensing capacitor, respectively, generating a differential signal for the power of the signal output according to the switching of the first input signal and the second input signal, and detecting the differential signal that changes according to the phase delay Od.

The object of the present disclosure is not limited to the object mentioned above, and other objects not mentioned will be clearly understood by those skilled in the art from the description below.

An apparatus for detecting a relative phase according to the present disclosure includes: a signal superposition unit configured to receive and switch a first input signal and a second input signal having a phase delay θ_{d} with respect to the first input signal so that the first input signal and the second input signal pass through a sensing resistor or a sensing capacitor, respectively, and to superpose and output the passed signals; a signal power detection unit configured to detect power of the signal output from the signal superposition unit; and a differential signal detection unit configured to generate a differential signal for the power of the signal output according to the switching of the first input signal and the second input signal in the signal superposition unit, and to detect the differential signal that changes according to the phase delay θ_{d}.

In an embodiment, the signal superposition unit may include: a switch network configured to switch and output the first input signal and the second input signal; a sensing resistor connected to one of output signals of the switch network; and a sensing capacitor having one terminal connected to one of the output signals of the switch network and the other terminal connected to the sensing resistor.

In an embodiment, the signal power detection unit may detect the power by receiving an output signal at a connection node of the sensing resistor and the sensing capacitor.

In an embodiment, the apparatus may further include a signal sampler configured to set, as a first sampling interval, an interval in which the first input signal passes through the sensing resistor and the second input signal passes through the sensing capacitor, to set, as a second sampling interval, an interval in which the first input signal passes through the sensing capacitor and the second input signal passes through the sensing resistor, as the switch network switches the signals, and to store the power of the output signal at the connection node in each of the first and second sampling intervals.

In an embodiment, the differential signal detection unit may generate a differential signal for the power of the output signal at the connection node in the first sampling interval and the second sampling interval, and detect the differential signal that changes according to the phase delay θ_{d}, the power being stored in the signal sampler.

A method for detecting a relative phase according to the present disclosure includes: receiving and switching, by a signal superposition unit, a first input signal and a second input signal having a phase delay θ_{d} with respect to the first input signal so that the first input signal and the second input signal pass through the sensing resistor or the sensing capacitor, respectively, and superposing and outputting the passed signals; detecting, by a signal power detection unit, power of the signal output from the signal superposition unit; and generating, by a differential signal detection unit, a differential signal for the power of the signal output according to the switching of the first input signal and the second input signal in the signal superposition unit, and detecting the differential signal that changes according to the phase delay θ_{d}.

In an embodiment, the detecting of the power of the output signal may include detecting the power by receiving an output signal at a connection node of the sensing resistor and the sensing capacitor.

In an embodiment, the method may further include setting, by a signal sampler, as a first sampling interval, an interval in which the first input signal passes through the sensing resistor and the second input signal passes through the sensing capacitor, setting, as a second sampling interval, an interval in which the first input signal passes through the sensing capacitor and the second input signal passes through the sensing resistor, as the signal superposition unit switches the signals, and storing the power of the output signal at the connection node in each of the first and second sampling intervals.

In an embodiment, the detecting of the differential signal may include generating, by the differential signal detection unit, a differential signal for the power of the output signal at the connection node in the first sampling interval and the second sampling interval, and detecting the differential signal that changes according to the phase delay θ_{d}, the power being stored in the signal sampler.

An embodiment of the present disclosure can provide an apparatus for detecting a relative phase with a simple structure by minimizing a circuit for measuring a relative phase of a signal, and a method for detecting a relative phase.

In addition, the apparatus has a simple structure, so that it is possible to provide an apparatus for detecting a relative phase with low power consumption and a method for detecting a relative phase.

Effects of the present disclosure which may be obtained in the present disclosure are not limited to the aforementioned effects, and other effects not described above may be evidently understood by a person having ordinary knowledge in the art to which the present disclosure pertains from the following description.

### BRIEF DESCRIPTION OF THE DRAWINGS

FIG. 1 is a diagram illustrating an apparatus for detecting a relative phase in the related art.

FIG. 2 is a diagram schematically illustrating an apparatus for detecting a relative phase according to an embodiment of the present disclosure.

FIG. 3 is a diagram schematically illustrating an example of a circuit configuration of a signal superposition unit in the apparatus for detecting a relative phase according to an embodiment of the present disclosure.

FIG. 4 is a diagram illustrating a first sampling interval of the apparatus for detecting a relative phase according to an embodiment of the present disclosure.

FIG. 5 is a diagram illustrating a case where there is no phase delay in the first sampling interval of the apparatus for detecting a relative phase according to an embodiment of the present disclosure.

FIG. 6 is a diagram illustrating a case where there is a phase delay in the first sampling interval of the apparatus for detecting a relative phase according to an embodiment of the present disclosure.

FIG. 7 is a diagram illustrating a second sampling interval of the apparatus for detecting a relative phase according to an embodiment of the present disclosure.

FIG. 8 is a diagram illustrating a case where there is no phase delay in the second sampling interval of the apparatus for detecting a relative phase according to an embodiment of the present disclosure.

FIG. 9 is a diagram illustrating a case where there is a phase delay in the second sampling interval of the apparatus for detecting a relative phase according to an embodiment of the present disclosure.

FIG. 10 is a diagram illustrating a simulation result for an output signal of the apparatus for detecting a relative phase due to a phase delay in the apparatus for detecting a relative phase according to an embodiment of the present disclosure.

FIG. 11 is a flowchart for explaining a method for detecting a relative phase according to an embodiment of the present disclosure.

FIG. 12 is a block diagram illustrating a computer system for implementing a method for detecting a relative phase according to an embodiment of the present disclosure.

### DETAILED DESCRIPTION

Advantages and characteristics of the present disclosure and a method for achieving the advantages and characteristics will become apparent from the embodiments described in detail later in conjunction with the accompanying drawings. However, the present disclosure is not limited to the disclosed embodiments, but may be implemented in various different forms. The embodiments are merely provided to complete the present disclosure and to fully notify a person having ordinary knowledge in the art to which the present disclosure pertains of the category of the present disclosure. The present disclosure is merely defined by the claims. Terms used in this specification are used to describe embodiments and are not intended to limit the present disclosure. In this specification, an expression of the singular number includes an expression of the plural number unless clearly defined otherwise in the context. The term “comprises” and/or “comprising” used in this specification does not exclude the presence or addition of one or more other elements, steps, operations, and/or elements in addition to a mentioned element, step, operation, and/or element.

In the description of the present disclosure, when it is determined that detailed descriptions of related publicly-known technologies may obscure the subject matter of the present disclosure, the detailed descriptions thereof is omitted.

Hereinafter, embodiments of the present disclosure are described in detail with reference to the accompanying drawings. In order to facilitate overall understanding in the description of the present disclosure, the same reference numbers are used for the same means regardless of the drawing number.

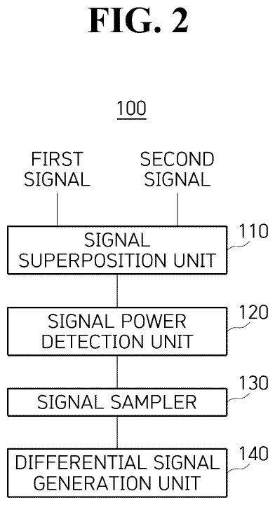

FIG. 2 is a diagram schematically illustrating an apparatus 100 for detecting a relative phase according to an embodiment of the present disclosure.

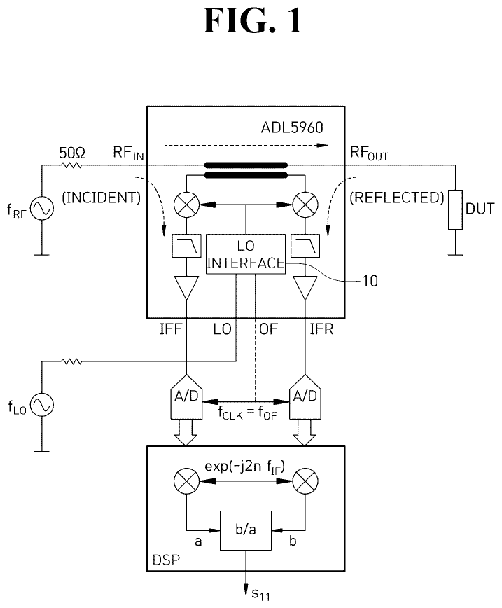

Referring to FIG. 2, the apparatus 100 for detecting a relative phase according to an embodiment of the present disclosure includes a signal superposition unit 110, a signal power detection unit 120, a signal sampler 130, and a differential signal generation unit 140. The apparatus 100 for detecting a relative phase illustrated in FIG. 1 is based on an embodiment, and the components of the apparatus 100 for detecting a relative phase according to the present disclosure are not limited to the embodiment illustrated in FIG. 1 and may be added, changed, or deleted as necessary.

The signal superposition unit 110 receives and switches a first input signal and a second input signal having a phase delay θ_{d} with respect to the first input signal so that the first input signal and the second input signal pass through a sensing resistor or a sensing capacitor, respectively, and superposes and outputs the passed signals. The first input signal and the second input signal are independent power sources, and the signal superposition unit 110 superposes the signals by applying the principle of superposition.

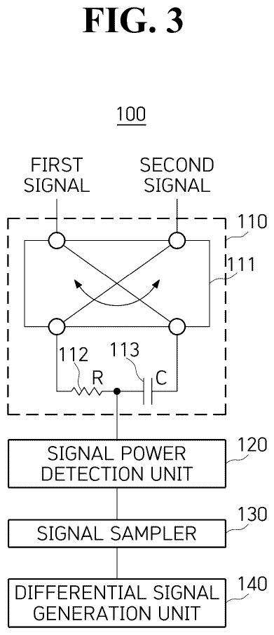

The signal superposition unit 110 may be implemented with various types of circuits. Hereinafter, an example of a specific circuit configuration of the signal superposition unit 110 is described with reference to FIG. 3.

FIG. 3 is a diagram schematically illustrating an example of a circuit configuration of the signal superposition unit in the apparatus for detecting a relative phase according to an embodiment of the present disclosure.

Referring to FIG. 3, the signal superposition unit 110 in the apparatus for detecting a relative phase according to an embodiment of the present disclosure includes a switch network 111 that switches and outputs the first input signal and the second input signal, a sensing resistor 112 connected to one of the output signals of the switch network 111, and a sensing capacitor 113 having one terminal connected to one of the output signals of the switch network 111 and the other terminal connected to the sensing resistor 112.

Accordingly, the signal superposition unit 110 may switch whether the first input signal or the second input signal passes through the sensing resistor 112 or the sensing capacitor 113.

In such a case, the signal power detection unit 120 detects the power of the signal output from the signal superposition unit 110. In an embodiment, the signal power detection unit 120 may measure an output signal when the first input signal or the second input signal passes through the sensing resistor 112 or the sensing capacitor 113, respectively. The signal power detection unit 120 may also detect the power by receiving an output signal at a connection node of the sensing resistor 112 and the sensing capacitor 113.

The apparatus 100 for detecting a relative phase according to an embodiment of the present disclosure may set two sampling intervals, that is, a first sampling interval and a second sampling interval, according to whether the first input signal or the second input signal passes through the sensing resistor 112 or the sensing capacitor 113, respectively, and perform a relative phase detection operation.

The signal sampler 130 sets, as a first sampling interval, an interval in which the first input signal passes through the sensing resistor 112 and the second input signal passes through the sensing capacitor 113, sets, as a second sampling interval, an interval in which the first input signal passes through the sensing capacitor 113 and the second input signal passes through the sensing resistor 112, as the switch network 111 switches the signals, and stores the power of the output signal at the connection node in each of the first and second sampling intervals.

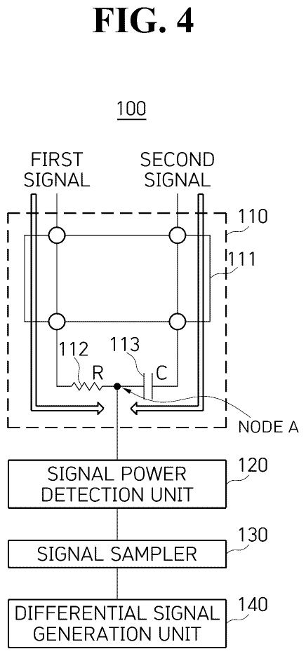

Hereinafter, the relative phase detection operation in the first sampling interval and the second sampling interval is described with reference to FIGS. 4 to 9.

FIG. 4 is a diagram illustrating the first sampling interval of the apparatus for detecting a relative phase according to an embodiment of the present disclosure.

Referring to FIG. 4, in the first sampling interval, the switch network 111 performs an operation of connecting a first signal to the sensing resistor 112 and connecting a second signal to the sensing capacitor 113. That is, in the first sampling interval, the signal power detection unit 120 measures an output signal when the first input signal passes through the sensing resistor 112 and an output signal when the second input signal passes through the sensing capacitor 113, superposes these output signals, and measures an output signal at a connection node A of the sensing resistor 112 and the sensing capacitor 113.

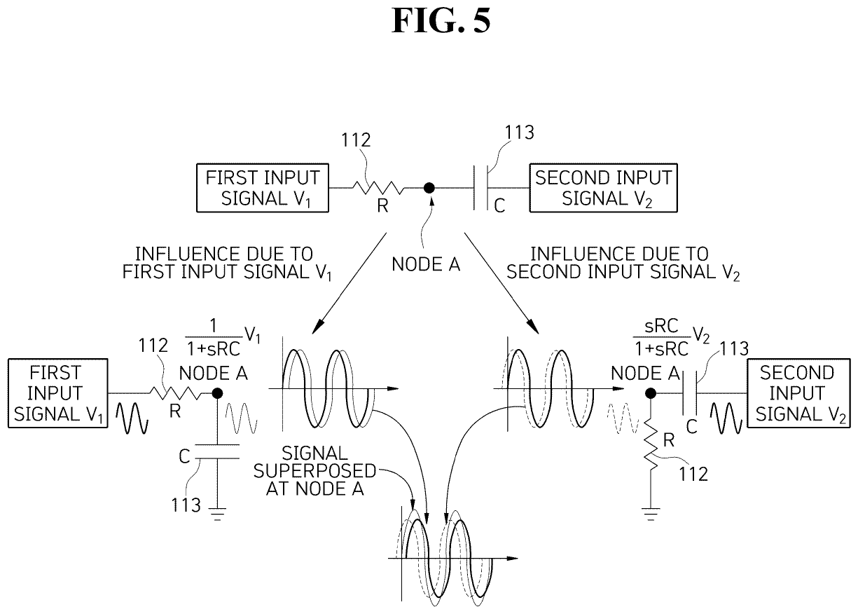

FIG. 5 is a diagram illustrating a case where there is no phase delay in the first sampling interval of the apparatus for detecting a relative phase according to an embodiment of the present disclosure.

In the above, the second input signal is mentioned as having a phase delay θ_{d} with respect to the first input signal in the signal superposition unit 110. However, the following description is given with reference to FIG. 5 on the assumption that the second input signal has no phase delay with respect to the first input signal.

In such a case, an output signal V₃ when the first input signal passes through the sensing resistor 112 may be expressed as Equation 1 below when V₁ is the first input signal, R is the resistance of the sensor resistor 112, C is the capacity of the sensor capacitor 113, and s=jw=j2πf, the output signal V₃ being measured by the signal power detection unit 120.

$${v}_{3} = \frac{1}{1 + s R C} {v}_{1} \qquad Equation l$$

An output waveform when the output signal V₃ with the transfer function shown in Equation 1 is output to the connection node is output with a certain positive delay compared to an input waveform in a specific frequency domain as illustrated on the left side of FIG. 5.

In addition, an output signal V₄ when the second input signal passes through the sensing capacitor 113 may be expressed as Equation 2 below when V₂ is the second input signal, R is the resistance of the sensor resistor 112, C is the capacity of the sensor capacitor 113, and s=jw=j2πf, the output signal V₄ being measured by the signal power detection unit 120.

$${v}_{4} = \frac{s R C}{1 + s R C} {v}_{2} \qquad Equation 2$$

An output waveform when the output signal V₄ with the transfer function shown in Equation 2 is output to the connection node is output with a certain negative delay compared to an input waveform in a specific frequency domain as illustrated on the right side of FIG. 5.

Accordingly, the output signal at the connection node of the sensing resistor 112 and the sensing capacitor 113 in the first sampling interval appears as the sum of the output signal V₃ and the output signal V₄, and the output waveform at this time is illustrated at the bottom of FIG. 5, the output signal being measured by the signal power detection unit 120.

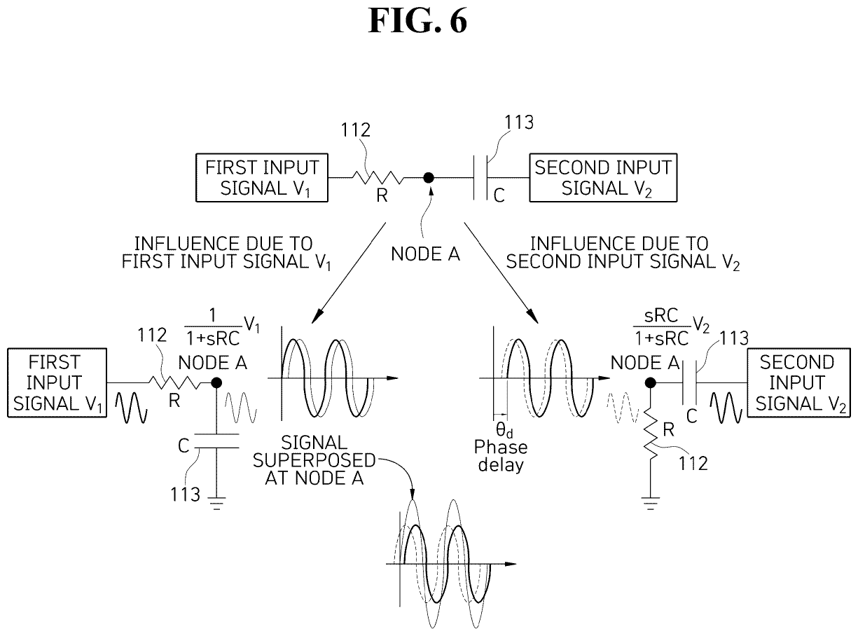

FIG. 6 is a diagram illustrating a case where there is a phase delay in the first sampling interval of the apparatus for detecting a relative phase according to an embodiment of the present disclosure.

As the second input signal is mentioned as having a phase delay θ_{d} with respect to the first input signal in the signal superposition unit 110, the following description is given with reference to FIG. 6 based on the fact that the second input signal has a phase delay θ_{d} with respect to the first input signal.

In the case of the first input signal, as in the case where there is no phase delay, an output waveform when the output signal V₃ with the transfer function shown in Equation 1 is output to the connection node is output with a certain positive delay compared to an input waveform in a specific frequency domain as illustrated on the left side of FIG. 6.

In the case of the second input signal, an output waveform when the output signal V₄ with the transfer function shown in Equation 2 is output to the connection node is output with a certain negative delay compared to an input waveform in a specific frequency domain. However, since the second input signal has a phase delay θ_{d}, the output waveform is located to the right compared to when there is no phase delay, as illustrated on the right side of FIG. 6.

Accordingly, the output signal at the connection node of the sensing resistor 112 and the sensing capacitor 113 in the first sampling interval appears as the sum of the output signal V₃ and the output signal V₄, and the output waveform at this time is illustrated at the bottom of FIG. 6, the output signal being measured by the signal power detection unit 120. Compared to the output waveform at the bottom of FIG. 5, it can be seen that the phases of the two output signals constructively interfere with each other due to the phase delay θ_{d} of the second input signal, and the magnitude of the superposed output signal becomes larger compared to when there is no phase delay.

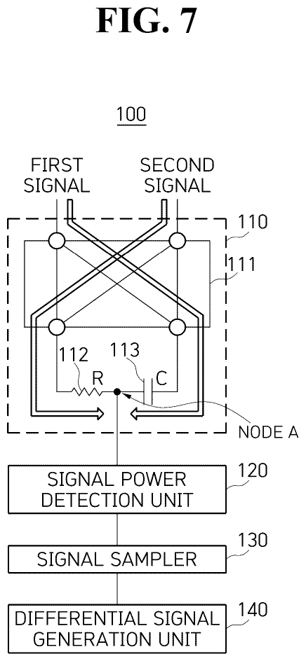

FIG. 7 is a diagram illustrating the second sampling interval of the apparatus for detecting a relative phase according to an embodiment of the present disclosure.

Referring to FIG. 7, in the second sampling interval, the switch network 111 performs an operation of connecting a first signal to the sensing capacitor 113 and connecting a second signal to the sensing resistor 112. That is, in the second sampling interval, the signal power detection unit 120 measures an output signal when the first input signal passes through the sensing capacitor 113 and an output signal when the second input signal passes through the sensing resistor 112, superposes these output signals, and measures an output signal at the connection node A of the sensing resistor 112 and the sensing capacitor 113.

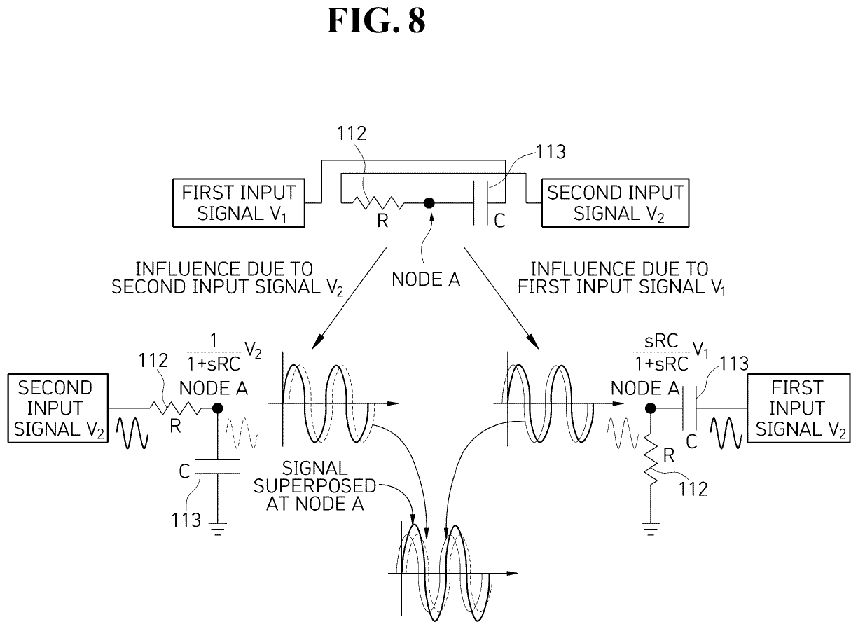

FIG. 8 is a diagram illustrating a case where there is no phase delay in the second sampling interval of the apparatus for detecting a relative phase according to an embodiment of the present disclosure.

In the above, the second input signal is mentioned as having a phase delay θ_{d} with respect to the first input signal in the signal superposition unit 110. However, the following description is given with reference to FIG. 8 on the assumption that the second input signal has no phase delay with respect to the first input signal.

In such a case, an output signal V₅ when the first input signal passes through the sensor capacitor 113 may be expressed as Equation 3 below when V₁ is the first input signal, R is the resistance of the sensor resistor 112, C is the capacity of the sensor capacitor 113, and s=jw=j2πf, the output signal V₅ being measured by the signal power detection unit 120.

$${v}_{5} = \frac{s R C}{1 + s R C} {v}_{1} \qquad Equation 3$$

An output waveform when the output signal V₅ with the transfer function shown in Equation 3 is output to the connection node is output with a certain negative delay compared to an input waveform in a specific frequency domain as illustrated on the right side of FIG. 8.

In addition, an output signal V₆ when the second input signal passes through the sensing resistor 112 may be expressed as Equation 4 below when V₂ is the second input signal, R is the resistance of the sensor resistor 112, C is the capacity of the sensor capacitor 113, and s=jw=j2πf, the output signal V₆ being measured by the signal power detection unit 120.

$${v}_{6} = \frac{1}{1 + s R C} {v}_{2} \qquad Equation 4$$

An output waveform when the output signal V₆ with the transfer function shown in Equation 4 is output to the connection node is output with a certain positive delay compared to an input waveform in a specific frequency domain as illustrated on the left side of FIG. 8.

Accordingly, the output signal at the connection node of the sensing resistor 112 and the sensing capacitor 113 in the second sampling interval appears as the sum of the output signal V₅ and the output signal V₆, and the output waveform at this time is illustrated at the bottom of FIG. 8, the output signal being measured by the signal power detection unit 120. It can be seen that this is the same as the output waveform illustrated at the bottom of FIG. 5 when there is no phase delay in the first sampling interval.

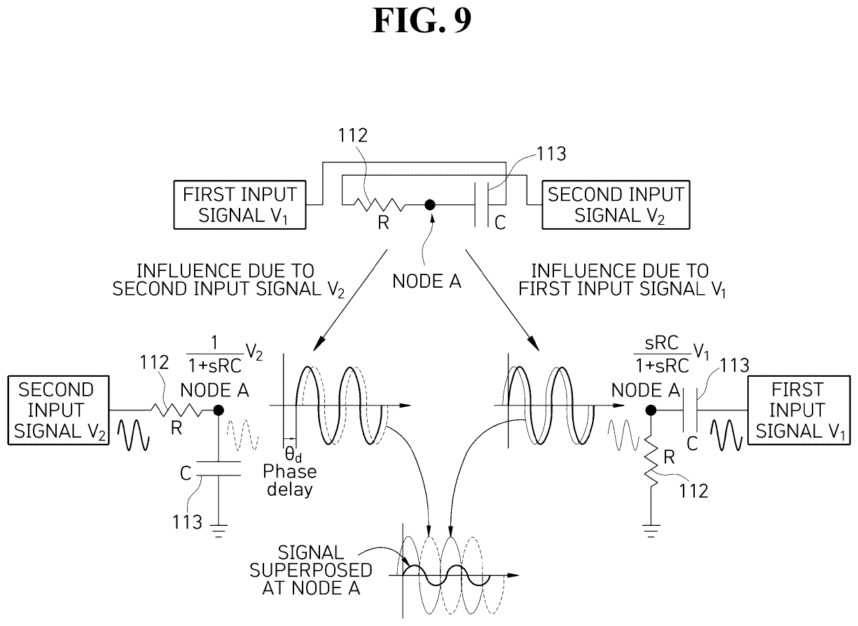

FIG. 9 is a diagram illustrating a case where there is a phase delay in the second sampling interval of the apparatus for detecting a relative phase according to an embodiment of the present disclosure.

As the second input signal is mentioned as having a phase delay θ_{d} with respect to the first input signal in the signal superposition unit 110, the following description is given with reference to FIG. 9 based on the fact that the second input signal has a phase delay θ_{d} with respect to the first input signal.

In the case of the first input signal, as in the case where there is no phase delay, an output waveform when the output signal V₅ with the transfer function shown in Equation 3 is output to the connection node is output with a certain negative delay compared to an input waveform in a specific frequency domain as illustrated on the right side of FIG. 9.

In the case of the second input signal, an output waveform when the output signal V₆ with the transfer function shown in Equation 4 is output to the connection node is output with a certain positive delay compared to an input waveform in a specific frequency domain. However, since the second input signal has a phase delay θ_{d}, the output waveform is located to the right compared to when there is no phase delay, as illustrated on the left side of FIG. 9. Therefore, the output signal V6 is output with a larger delay than before due to an additional positive delay caused by an RC network in addition to the phase delay θ_{d}.

Accordingly, the output signal at the connection node of the sensing resistor 112 and the sensing capacitor 113 in the first sampling interval appears as the sum of the output signal V₅ and the output signal V₆, and the output waveform at this time is illustrated at the bottom of FIG. 9, the output signal being measured by the signal power detection unit 120. Compared to the output waveform at the bottom of FIG. 8, it can be seen that destructive interference occurs between the phase of the output signal V₆ and the phase of the output signal V₅ due to the phase delay θ_{d} of the second input signal and the magnitude of the sum of the two signals is reduced.

As described above, according to the relative phase detection operation in the apparatus 100 for detecting a relative phase according to an embodiment of the present disclosure, it can be seen that the sum of the two output signals in the first sampling interval and the second sampling interval changes depending on the phase delay θ_{d} of the second signal V₂ and the direction of the change is opposite to each other.

Accordingly, in the first sampling interval and the second sampling interval, the magnitude of the sum of the two output signals at the connection node of the sensing resistor 112 and the sensing capacitor 113 may be detected through the signal power detection unit 120, and then the power of the signal detected in each sampling interval through the signal sampler 130 may be stored. Finally, the differential signal generation unit 140 may generate a differential signal for the power of the output signal at the connection node in the first sampling interval and the second sampling interval, and detect the differential signal that changes according to the phase delay θ_{d}, the power being stored in the signal sampler.

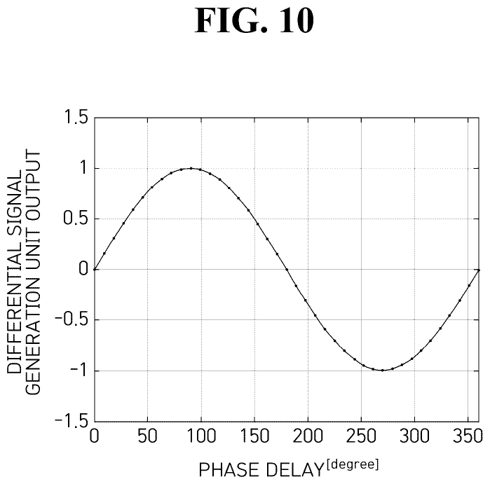

FIG. 10 is a diagram illustrating a simulation result for an output signal of the apparatus for detecting a relative phase due to a phase delay in the apparatus for detecting a relative phase according to an embodiment of the present disclosure.

FIG. 10 illustrates, when two signals with the same magnitude but different phase delays are input to the apparatus 100 for detecting a relative phase according to an embodiment of the present disclosure, a normalized simulation result for an output signal of the apparatus 100 for detecting a relative phase due to a phase delay. An input signal used in the simulation test was a continuous wave (CW) signal in a 1 GHz frequency band, with a phase delay difference of 0° to 360°, and was input to the apparatus 100 for detecting a relative phase according to an embodiment of the present disclosure.

From the simulation result, it can be seen that an output value of the differential signal generation unit 140 changes according to the phase delay in the apparatus 100 for detecting a relative phase according to the present disclosure.

The above has described a configuration in which the signal superposition unit 110 in the apparatus 100 for detecting a relative phase according to an embodiment of the present disclosure switches the first input signal and the second input signal by using the switch network 111 and detects a relative phase through the first sampling interval and the second sampling interval.

In another embodiment, the apparatus 100 for detecting a relative phase according to an embodiment of the present disclosure may implement an apparatus 100 for detecting a relative phase that detects a relative phase through the first sampling interval and the second sampling interval without switching the first input signal and the second input signal. However, in such a case, since no differential signal is generated, an output signal of the apparatus 100 for detecting a relative phase may not be constant depending on the phase delay. However, in the apparatus 100 for detecting a relative phase according to an embodiment of the present disclosure, since the first signal and the second signal are completely switched between the sensing resistor 112 and the sensing capacitor 113 through the switch network 111 and are differentially input, it has the advantage of being able to attenuate asymmetry that may occur in a circuit and other parts.

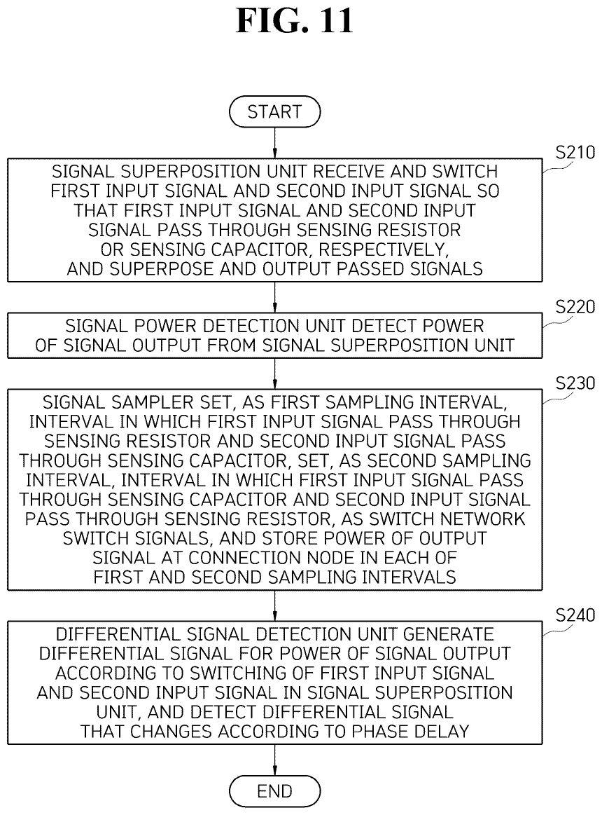

FIG. 11 is a flowchart for explaining a method for detecting a relative phase according to an embodiment of the present disclosure.

As illustrated in FIG. 11, the method for detecting a relative phase according to an embodiment of the present disclosure may include steps S210, S220, S230, and S240.

Step S210 is a step in which the signal superposition unit receives and switches the first input signal and the second input signal having a phase delay θ_{d} with respect to the first input signal so that the first input signal and the second input signal pass through the sensing resistor or the sensing capacitor, respectively, and superposes and outputs the passed signals.

Step S220 is a step in which the signal power detection unit detects the power of the signal output from the signal superposition unit. In an embodiment, step S220 may include a step of detecting the power by receiving the output signal at the connection node of the sensing resistor and the sensing capacitor.

Step S230 is a step in which the signal sampler sets, as a first sampling interval, an interval in which the first input signal passes through the sensing resistor and the second input signal passes through the sensing capacitor, sets, as a second sampling interval, an interval in which the first input signal passes through the sensing capacitor and the second input signal passes through the sensing resistor, as the switch network switches the signals, and stores the power of the output signal at the connection node in each of the first and second sampling intervals.

Step S240 is a step in which the differential signal detection unit generates a differential signal for the power of the signal output according to the switching of the first input signal and the second input signal in the signal superposition unit, and to detect the differential signal that changes according to the phase delay θ_{d}. In an embodiment, step S240 may include a step in which the differential signal detection unit generates a differential signal for the power of the output signal at the connection node in the first sampling interval and the second sampling interval, and detects the differential signal that changes according to the phase delay θ_{d}, the power being stored in the signal sampler.

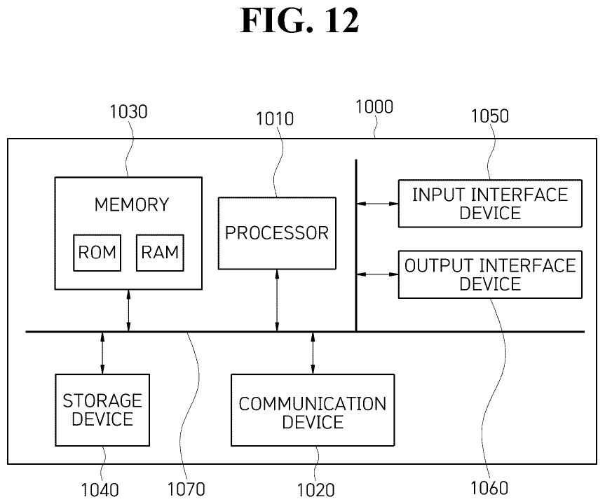

FIG. 12 is a block diagram illustrating a computer system for implementing a method for detecting a relative phase according to an embodiment of the present disclosure.

Referring to FIG. 12, a computer system 1000 may include at least one of a processor 1010, a memory 1030, an input interface device 1050, an output interface device 1060, and a storage device 1040 that communicate with one another through a bus 1070. The computer system 1000 may also include a communication device 1020 coupled to a network. The processor 1010 may be a central processing unit (CPU) or a semiconductor device that executes instructions stored in the memory 1030 or the storage device 1040. The memory 1030 and the storage device 1040 may include various types of volatile or nonvolatile storage media. For example, the memory may include a read only memory (ROM) and a random access memory (RAM). In an embodiment of the present disclosure, the memory may be located inside or outside the processor, and may be connected to the processor through various known means.

The memory is various forms of volatile or nonvolatile storage media, and for example, may include a read-only memory (ROM) or a random access memory (RAM).

Accordingly, an embodiment of the present disclosure may be implemented as a computer-implemented method or a non-transitory computer-readable medium storing computer-executable instructions. In an embodiment, when executed by a processor, computer-readable instructions may perform a method according to at least one aspect of the present disclosure.

The communication device 1020 may transmit or receive wired signals or wireless signals.

The method according to an embodiment of the present disclosure may be implemented in the form of program instructions that can be executed through various computer means, and recorded on a computer-readable medium.

The computer-readable medium may include program instructions, data files, data structures, and the like singly or in combination. The program instructions recorded on the computer-readable medium may be specially designed and configured for an embodiment of the present disclosure, or may be known to and usable by those skilled in the art of computer software. A computer-readable recording medium may include a hardware device configured to store and execute program instructions. Examples of the computer-readable recording medium may include magnetic media such as hard disks, floppy disks, and magnetic tapes, optical media such as CD-ROMs and DVDs, and magneto-optical media such as floptical disks, a ROM, a RAM, and a flash memory. The program instructions may include not only machine language code such as that generated by a compiler, but also high-level language code that can be executed by a computer through an interpreter or the like.

For reference, the components according to an embodiment of the present disclosure may be implemented in the form of software or hardware such as a digital signal processor (DSP), a field programmable gate array (FPGA), or an application specific integrated circuit (ASIC), and may perform predetermined roles.

However, the term ‘components’ are not limited to software or hardware, and each component may be configured to reside in an addressable storage medium or to reproduce one or more processors.

Accordingly, as an example, the components include components such as software components, object-oriented software components, class components, and task components, processes, functions, attributes, procedures, subroutines, segments of a program code, drivers, firmware, microcode, circuitry, data, databases, data structures, tables, arrays, and variables.

Components and functions provided within the components may be combined into a smaller number of components or further divided into additional components.

On the other hand, it will be understood that each block of the flowchart and combinations of the flowchart may be performed by computer program instructions. These computer program instructions may be loaded on a processor of a general purpose computer, a special purpose computer, or other programmable data processing equipment, so that the instructions, which are executed via the processor of the computer or other programmable data processing equipment, generate means for performing the functions described in the block(s) of the flowchart. The computer program instructions may also be loaded on the computer or other programmable data processing equipment, so that a series of operation steps are performed on the computer or other programmable data processing equipment to produce a computer-implemented process, thereby allowing the instructions executed on the computer or other programmable data processing equipment to provide steps for performing the functions described in the block(s) of the flowchart.

Furthermore, each block may represent a module, a segment, or a part of a code that includes one or more executable instructions for performing specified logical function(s). It should be noted that in some alternative implementations, the functions mentioned in the blocks may occur out of order. For example, two blocks shown one after another may be performed substantially simultaneously, or the blocks may sometimes be performed in the reverse order according to a corresponding function.

The term ‘ . . . unit’ or ‘ . . . module’ used in the present embodiment means software or hardware components such as FPGA or ASIC, and the ‘ . . . unit’ or ‘ . . . module’ performs certain roles. However, the ‘ . . . unit’ or ‘ . . . module’ is not limited to software or hardware. The ‘ . . . unit’ or ‘ . . . module’ may be configured to reside in an addressable storage medium or may be configured to reproduce one or more processors. Accordingly, as an example, the ‘ . . . unit’ or ‘ . . . module’ includes components such as software components, object-oriented software components, class components, and task components, processes, functions, attributes, procedures, subroutines, segments of a program code, drivers, firmware, microcode, circuitry, data, databases, data structures, tables, arrays, and variables. Components and functions provided within the ‘ . . . unit’ or ‘ . . . module’ may be combined into a smaller number of components and the ‘ . . . unit’ or ‘ . . . module’ or further divided into additional components and the ‘ . . . unit’ or ‘ . . . modules’. In addition, the components and the ‘ . . . unit’ or ‘ . . . modules’ may be implemented to reproduce one or more CPUs in a device or a secure multimedia card.

Although preferred embodiments of the present disclosure have been described above, those skilled in the art will understand that various modifications and changes can be made to the present disclosure without departing from the spirit and scope of the present disclosure as set forth in the claims below.

What is claimed is:

1. An apparatus for detecting a relative phase, comprising:
a signal superposition unit configured to receive and switch a first input signal and a second input signal having a phase delay θ_{d} with respect to the first input signal so that the first input signal and the second input signal pass through a sensing resistor or a sensing capacitor, respectively, and to superpose and output the passed signals;
a signal power detection unit configured to detect power of the signal output from the signal superposition unit; and
a differential signal detection unit configured to generate a differential signal for the power of the signal output according to the switching of the first input signal and the second input signal in the signal superposition unit, and to detect the differential signal that changes according to the phase delay θ_{d}.

2. The apparatus for detecting a relative phase of claim 1, wherein the signal superposition unit comprises:
a switch network configured to switch and output the first input signal and the second input signal;
a sensing resistor connected to one of output signals of the switch network; and
a sensing capacitor having one terminal connected to one of the output signals of the switch network and the other terminal connected to the sensing resistor.

3. The apparatus for detecting a relative phase of claim 2, wherein the signal power detection unit detects the power by receiving an output signal at a connection node of the sensing resistor and the sensing capacitor.

4. The apparatus for detecting a relative phase of claim 3, further comprising:
a signal sampler configured to set, as a first sampling interval, an interval in which the first input signal passes through the sensing resistor and the second input signal passes through the sensing capacitor, to set, as a second sampling interval, an interval in which the first input signal passes through the sensing capacitor and the second input signal passes through the sensing resistor, as the switch network switches the signals, and to store the power of the output signal at the connection node in each of the first and second sampling intervals.

5. The apparatus for detecting a relative phase of claim 4, wherein an output signal V₃ when the first input signal passes through the sensing resistor is expressed as Equation below when V₁ is the first input signal, R is resistance of the sensor resistor, C is capacity of the sensor capacitor, and s=jw=j2πf, the output signal V₃ being measured by the signal power detection unit
$${v}_{3} = \frac{1}{1 + s R C} {v}_{1} \qquad Equation$$

6. The apparatus for detecting a relative phase of claim 5, wherein an output signal V₄ when the second input signal passes through the sensing capacitor is expressed as Equation below when V₂ is the second input signal, R is the resistance of the sensor resistor, C is the capacity of the sensor capacitor, and s=jw=j2πf, the output signal V₄ being measured by the signal power detection unit.
$${v}_{4} = \frac{s R C}{1 + s R C} {v}_{2} \qquad Equation$$

7. The apparatus for detecting a relative phase of claim 6, wherein the output signal at the connection node of the sensing resistor and the sensing capacitor in the first sampling interval appears as a sum of the output signal V₃ and the output signal V₄, the output signal being measured by the signal power detection unit.

8. The apparatus for detecting a relative phase of claim 4, wherein an output signal V₅ when the first input signal passes through the sensor capacitor is expressed as Equation below when V₁ is the first input signal, R is the resistance of the sensor resistor, C is the capacity of the sensor capacitor, and s=jw=j2πf, the output signal V₅ being measured by the signal power detection unit.
$${v}_{5} = \frac{s R C}{1 + s R C} {v}_{1} \qquad Equation$$

9. The apparatus for detecting a relative phase of claim 8, wherein an output signal V₆ when the second input signal passes through the sensing resistor is expressed as Equation below when V₂ is the second input signal, R is the resistance of the sensor resistor, C is the capacity of the sensor capacitor, and s=jw=j2πf, the output signal V₆ being measured by the signal power detection unit.
$${v}_{6} = \frac{1}{1 + s R C} {v}_{2} \qquad Equation$$

10. The apparatus for detecting a relative phase of claim 9, wherein the output signal at the connection node of the sensing resistor and the sensing capacitor in the second sampling interval appears as a sum of the output signal V₅ and the output signal V₆, the output signal being measured by the signal power detection unit.

11. The apparatus for detecting a relative phase of claim 4, wherein the differential signal detection unit generates a differential signal for the power of the output signal at the connection node in the first sampling interval and the second sampling interval, and detects the differential signal that changes according to the phase delay θ_{d}, the power being stored in the signal sampler.

12. A method for detecting a relative phase, comprising:
receiving and switching, by a signal superposition unit, a first input signal and a second input signal having a phase delay θ_{d} with respect to the first input signal so that the first input signal and the second input signal pass through the sensing resistor or the sensing capacitor, respectively, and superposing and outputting the passed signals;
detecting, by a signal power detection unit, power of the signal output from the signal superposition unit; and
generating, by a differential signal detection unit, a differential signal for the power of the signal output according to the switching of the first input signal and the second input signal in the signal superposition unit, and detecting the differential signal that changes according to the phase delay θ_{d}.

13. The method for detecting a relative phase of claim 12, wherein the detecting of the power of the output signal comprises:
detecting the power by receiving an output signal at a connection node of the sensing resistor and the sensing capacitor.

14. The method for detecting a relative phase of claim 13, further comprising:
setting, by a signal sampler, as a first sampling interval, an interval in which the first input signal passes through the sensing resistor and the second input signal passes through the sensing capacitor, setting, as a second sampling interval, an interval in which the first input signal passes through the sensing capacitor and the second input signal passes through the sensing resistor, as the signal superposition unit switches the signals, and storing the power of the output signal at the connection node in each of the first and second sampling intervals.

15. The method for detecting a relative phase of claim 14, wherein the detecting of the differential signal comprises:
generating, by the differential signal detection unit, a differential signal for the power of the output signal at the connection node in the first sampling interval and the second sampling interval, and detecting the differential signal that changes according to the phase delay θ_{d}, the power being stored in the signal sampler.
